(19) United States
(12) Patent Application Publication
(10) Pub. No.: US 2010/0031997 A1
(43) Pub. Date: Feb. 11, 2010

(54) FLEXIBLE THIN FILM PHOTOVOLTAIC MODULES AND MANUFACTURING THE SAME

(76) Inventor: Bulent M. Basol, Manhattan Beach, CA (US)

Correspondence Address: PILLSBURY WINTHROP SHAW PITTMAN LLP, P.O. BOX 10500, MCLEAN, VA, 22102, US

(21) Appl. No.: 12/372,737

(22) Filed: Feb. 17, 2009

Related U.S. Application Data
(63) Continuation-in-part of application No. 12/250,507, filed on Oct. 13, 2008.
Application No. 12/250,507 is a continuation-in-part of application No. 12/189,627, filed on Aug. 11, 2008.
(60) Provisional application No. 61/097,628, filed on Sep. 17, 2008.
(60) Provisional application No. 61/117,083, filed on Nov. 21, 2008.
(60) Provisional application No. 61/145,947, filed on Jan. 20, 2009.

(51) Int. Cl. H01L 31/042; H01L 31/18

(52) U.S. Cl. 136/244; 438/61

(57) ABSTRACT

A continuous flexible sheet for use in fabricating flexible solar cell modules is provided. The continuous flexible sheet includes an elongated protective sheet having a front surface and a back surface. The back surface includes at least two barrier regions and an at least one separation region. At least two moisture barrier layers attached to the at least two barrier regions. The at least one separation region surrounds and physically separates the at least two barrier layers attached to the at least two barrier regions.

### CLAIM OF PRIORITY

This application is a Continuation-in-Part of U.S. patent application Ser. No. 12/250,507, filed on Oct. 13, 2008, entitled “Structure and Method of Manufacturing Thin Film Photovoltaic Modules;” which is a Continuation-in-Part of U.S. patent application Ser. No. 12/189,627, filed Aug. 11, 2008, entitled “Photovoltaic Modules with Improved Reliability;” and this application relates to and claims priority from both of these applications; and this application also relates to and claims priority from U.S. Provisional Application No. 61/097,628, filed Sep. 17, 2008, entitled “Method of Manufacturing Flexible Thin Film Photovoltaic Modules;” this application also relates to and claims priority from U.S. Provisional Application No. 61/117,083, filed Nov. 21, 2008 entitled “Flexible Thin Film Photovoltaic Modules and Manufacturing the Same;” and this application also relates to and claims priority from U.S. Provisional Application No. 61/145,947, filed Jan. 20, 2009, entitled “Flexible Thin Film Photovoltaic Modules and Manufacturing the Same,” all of which are expressly incorporated herein by reference.

### BACKGROUND

1. Field of the Inventions

The aspects and advantages of the present inventions generally relate to apparatus and methods of photovoltaic or solar module design and fabrication and, more particularly, to roll-to-roll or continuous packaging techniques for flexible modules employing thin film solar cells.

2. Description of the Related Art

Solar cells are photovoltaic devices that convert sunlight directly into electrical power. The most common solar cell material is silicon, which is in the form of single or polycrystalline wafers. However, the cost of electricity generated using silicon-based solar cells is higher than the cost of electricity generated by the more traditional methods. Therefore, since early 1970's there has been an effort to reduce cost of solar cells for terrestrial use. One way of reducing the cost of solar cells is to develop low-cost thin film growth techniques that can deposit solar-cell-quality absorber materials on large area substrates and to fabricate these devices using high-throughput, low-cost methods.

Group IBIIIAVIA compound semiconductors comprising some of the Group IB (Cu, Ag, Au), Group IIIA (B, Al, Ga, In, Ti) and Group VIA (O, S, Se, Te, Po) materials or elements of the periodic table are excellent absorber materials for thin film solar cell structures. Especially, compounds of Cu, In, Ga, Se and S which are generally referred to as CIGS(S), or Cu(In,Ga)(S,Se)₂ or CuIn₁₋ₓGaₓ(S_{y}Se_{1-y})ₖ, where 0≦x≦1, 0≦y≦1 and k is approximately 2, have already been employed in solar cell structures that yielded conversion efficiencies approaching 20%. Therefore, in summary, compounds containing: i) Cu from Group IB, ii) at least one of In, Ga and Al from Group IIIA, and iii) at least one of S, Se, and Te from Group VIA, are of great interest for solar cell applications. It should be noted that although the chemical formula for CIGS(S) is often written as Cu(In,Ga)(S,Se)₂, a more accurate formula for the compound is Cu(In,Ga)(S,Se)ₖ, where k is typically close to 2 but may not be exactly 2. For simplicity, the value of k will be used as 2. It should be further noted that the notation “Cu(X,Y)” in the chemical formula means all chemical compositions of X and Y from (X=0% and Y=100%) to (X=100% and Y=0%). For example, Cu(In,Ga) means all compositions from CuIn to CuGa. Similarly, Cu(In,Ga)(S,Se)₂ means the whole family of compounds with Ga/(Ga+In) molar ratio varying from 0 to 1, and Se/(Se+S) molar ratio varying from 0 to 1.

The structure of a conventional Group IBIIIAVIA compound photovoltaic cell such as a Cu(In,Ga,Al)(S,Se,Te)₂ thin film solar cell is shown in FIG. 1. A photovoltaic cell 10 is fabricated on a substrate 11, such as a sheet of glass, a sheet of metal, an insulating foil or web, or a conductive foil or web. An absorber film 12, which includes a material in the family of Cu(In,Ga,Al)(S,Se,Te)₂, is grown over a conductive layer 13 or contact layer, which is previously deposited on the substrate 11 and which acts as the electrical contact to the device. The substrate 11 and the conductive layer 13 form a base 20 on which the absorber film 12 is formed. Various conductive layers comprising Mo, Ta, W, Ti, and their nitrides have been used in the solar cell structure of FIG. 1. If the substrate itself is a properly selected conductive material, it is possible not to use the conductive layer 13, since the substrate 11 may then be used as the ohmic contact to the device. After the absorber film 12 is grown, a transparent layer 14 such as a CdS, ZnO, CdS/ZnO or CdS/ZnO/ITO stack is formed on the absorber film 12. Radiation 15 enters the device through the transparent layer 14. Metallic grids (not shown) may also be deposited over the transparent layer 14 to reduce the effective series resistance of the device. The preferred electrical type of the absorber film 12 is p-type, and the preferred electrical type of the transparent layer 14 is n-type. However, an n-type absorber and a p-type window layer can also be utilized. The preferred device structure of FIG. 1 is called a “substrate-type” structure. A “superstrate-type” structure can also be constructed by depositing a transparent conductive layer on a transparent superstrate such as glass or transparent polymeric foil, and then depositing the Cu(In,Ga,Al)(S,Se,Te)₂ absorber film, and finally forming an ohmic contact to the device by a conductive layer. In this superstrate structure light enters the device from the transparent superstrate side.

There are two different approaches for manufacturing PV modules. In one approach that is applicable to thin film CdTe, amorphous Si and CIGS technologies, the solar cells are deposited or formed on an insulating substrate such as glass that also serves as a back protective sheet or a front protective sheet, depending upon whether the device is “substrate-type” or “superstrate-type”, respectively. In this case the solar cells are electrically interconnected as they are deposited on the substrate. In other words, the solar cells are monolithically integrated on the single-piece substrate as they are formed. These modules are monolithically integrated structures. For CdTe thin film technology the superstrate is glass which also is the front protective sheet for the monolithically integrated module. In CIGS technology the substrate is glass or polyimide and serves as the back protective sheet for the monolithically integrated module. In monolithically integrated module structures, after the formation of solar cells which are already integrated and electrically interconnected in series on the substrate or superstrate, an encapsulant is placed over the integrated module structure and a protective sheet is attached to the encapsulant. An edge seal may also be formed along the edge of the module to prevent water vapor or liquid transmission through the edge into the monolithically integrated module structure.

In standard Si module technologies, and for CIGS and amorphous Si cells that are fabricated on conductive substrates such as aluminum or stainless steel foils, the solar cells are not deposited or formed on the protective sheet. They are separately manufactured and then the manufactured solar cells are electrically interconnected by stringing them or shingling them to form solar cell strings. In the stringing or shingling process, the (+) terminal of one cell is typically electrically connected to the (−) terminal of the adjacent device. For the Group IBIIIAVIA compound solar cell shown in FIG. 1, if the substrate 11 is conductive such as a metallic foil, then the substrate, which is the bottom contact of the cell, constitutes the (+) terminal of the device. The metallic grid (not shown) deposited on the transparent layer 14 is the top contact of the device and constitutes the (−) terminal of the cell. In shingling, individual cells are placed in a staggered manner so that a bottom surface of one cell, i.e. the (+) terminal, makes direct physical and electrical contact to a top surface, i.e. the (−) terminal, of an adjacent cell. Therefore, there is no gap between two shingled cells. Stringing is typically done by placing the cells side by side with a small gap between them and using conductive wires or ribbons that connect the (+) terminal of one cell to the (−) terminal of an adjacent cell. Solar cell strings obtained by stringing or shingling individual solar cells are interconnected to form circuits. Circuits may then be packaged in protective packages to form modules. Each module typically includes a plurality of strings of solar cells which are electrically connected to one another. The solar modules are constructed using various packaging materials to mechanically support and protect the solar cells in them against mechanical damage. The most common packaging technology involves lamination of circuits in transparent encapsulants. In a lamination process, in general, the electrically interconnected solar cells are covered with a transparent and flexible encapsulant layer which fills any hollow space among the cells and tightly seals them into a module structure, preferably covering both of their surfaces. A variety of materials are used as encapsulants, for packaging solar cell modules, such as ethylene vinyl acetate copolymer (EVA), thermoplastic polyurethanes (TPU), and silicones. However, in general, such encapsulant materials are moisture permeable; therefore, they must be further sealed from the environment by a protective shell, which forms resistance to moisture transmission into the module package. The nature of the protective shell determines the amount of water that can enter the package. The protective shell includes a front protective sheet and a back protective sheet and optionally an edge sealant that is at the periphery of the module structure (see for example, published application WO/2003/050891, “Sealed Thin Film PV Modules”). The top protective sheet is typically glass which is water impermeable. The back protective sheet may be a sheet of glass or a polymeric sheet such as TEDLAR® (a product of DuPont). The back protective polymeric sheet may or may not have a moisture barrier layer in its structure such as a metallic film like an aluminum film. Light enters the module through the front protective sheet. The edge sealant, which is presently used in thin film CdTe modules with glass/glass structure, is a moisture barrier material that may be in the form of a viscous fluid which may be dispensed from a nozzle to the peripheral edge of the module structure or it may be in the form of a tape which may be applied to the peripheral edge of the module structure. The edge sealant in Si-based modules is not between the top and bottom protective sheets but rather in the frame which is attached to the edge of the module. Moisture barrier characteristics of edge seals used for Si-based modules are not adequate for CIGS based modules as will be discussed later.

Flexible module structures may be constructed using flexible CIGS or amorphous Si solar cells. Flexible modules are light weight, and unlike the standard glass based Si solar modules, are un-breakable. Therefore, packaging and transportation costs for flexible modules are much lower. However, packaging of flexible structures are more challenging. Glass handling equipment used in glass based PV module manufacturing are fully developed by many equipment suppliers. Handling of flexible sheets cannot be carried out using such standard equipment. The flexible sheets that constitute the various layers in the flexible module structure may be cut into sizes that are close to the desired area of the module, and then the standard module encapsulation procedures may be carried out by handling and moving these pieces around. A more manufacturing friendly approach for flexible module manufacturing is needed to increase the reliability of such modules and reduce their manufacturing cost. Some prior art processing approaches for flexible amorphous Si based device fabrication are described in U.S. Pat. Nos. 4,746,618, 4,773,944, 5,131,954, 5,968,287, 5,457,057 and 5,273,608.

### SUMMARY

The aspects and advantages of the present inventions generally relate to apparatus and methods of photovoltaic or solar module design and fabrication and, more particularly, to roll-to-roll or continuous packaging techniques for flexible modules employing thin film solar cells.

In a particular embodiment is provided an apparatus comprising: a continuous flexible sheet for use in fabricating flexible solar cell modules, the continuous flexible sheet including: a front surface and a back surface, one of the front surface and the back surface including at least two moisture barrier regions and a separation region, wherein the separation region surrounds each moisture barrier region and physically separates adjacent moisture barrier regions; and a moisture barrier layer formed on each of the moisture barrier regions but not on the separation region.

In another embodiment there is described a monolithically integrated multi-module power supply, the monolithically integrated multi-module power supply including moisture barrier layers covering each of the ceilings of each of a plurality of sealed chambers that hold two solar cells that are electrically interconnected.

In further embodiments described methods of manufacturing a photovoltaic module.

### BRIEF DESCRIPTION OF THE DRAWINGS

These and other aspects and features of the present invention will become apparent to those of ordinary skill in the art upon review of the following description of specific embodiments of the invention in conjunction with the accompanying figures, wherein:

FIG. 1 is a schematic view a thin film solar cell;

FIG. 2A is a schematic cross sectional view of a flexible thin film solar module;

FIG. 2B is a schematic top view of the module of FIG. 2A;

FIGS. 3A-3F are schematic views of an embodiment of manufacturing of a continuous packaging structure of the present invention including a plurality of module structures;

FIGS. 4A-4B are schematic views of transforming the continuous packaging structure into a continuous multi-module power device including a plurality of solar modules;

FIG. 5 is a schematic side view of a solar module of the present invention;

FIGS. 6A-6B are schematic views of an embodiment of manufacturing monolithically integrated multi-module power supplies; and

FIG. 7 is a schematic view of a roll to roll system to manufacture flexible photovoltaic modules of the present invention.

FIG. 8 exemplifies a monolithically integrated multi-module power supply 600 having electrical leads with the first configuration.

FIG. 9 exemplifies a monolithically integrated multi-module power supply 700 having electrical leads with the second configuration due to the odd numbered row of solar cells.

FIG. 10 exemplifies a monolithically integrated multi-module power supply 800 having electrical leads with the first configuration due to the even numbered row of solar cells.

FIG. 11 exemplifies a monolithically integrated multi-module power supply 900 having electrical leads with the second configuration due to the odd numbered row of solar cells.

FIG. 12A is a schematic view of a solar cell module according to one embodiment;

FIG. 12B is a schematic cross sectional view of the solar cell module shown in FIG. 12A taken along the line F1-F2;

FIGS. 13A-13B show a process of manufacturing another embodiment of a continuous packaging structure.

FIG. 13C shows the completed structure of the continuous packaging structure of the embodiment made according to the process described in FIGS. 13A-13B.

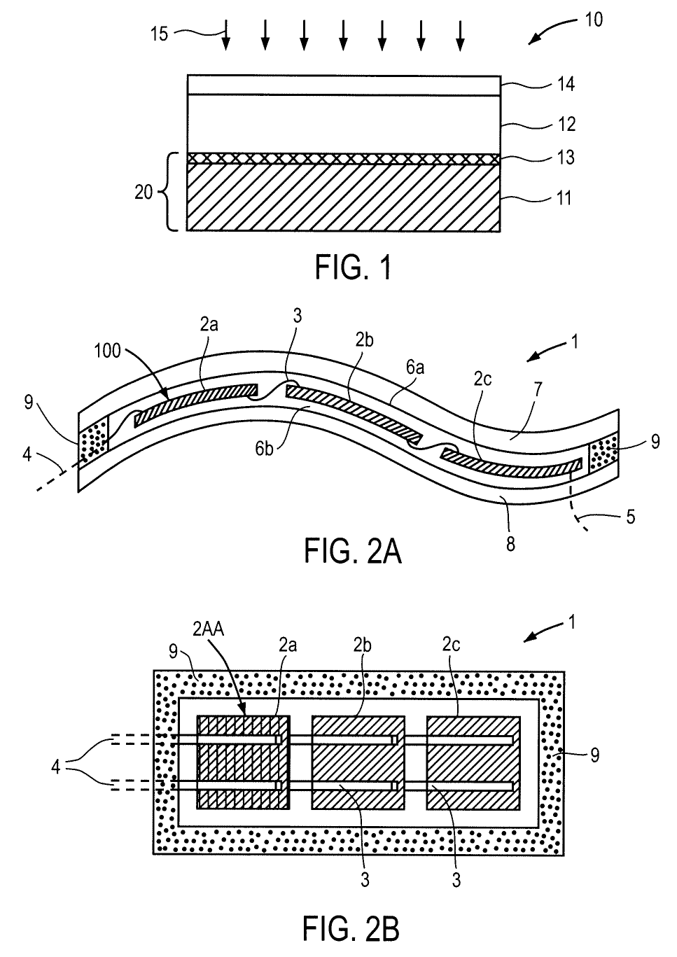

### DETAILED DESCRIPTION OF THE PREFERRED EMBODIMENTS

The preferred embodiments described herein provide methods of manufacturing flexible photovoltaic modules employing thin film Group IBIIIAVIA compound solar cells. The modules each include a moisture resistant protective shell within which flexible interconnected solar cells or cell strings are packaged and protected. The protective shell comprises a moisture barrier top protective sheet through which the light may enter the module, a moisture barrier bottom protective sheet, a support material or encapsulant covering at least one of a front side and a back side of each cell or cell string. The support material may preferably be used to fully encapsulate each solar cell and each string, top and bottom. The protective shell additionally comprises a moisture sealant that is placed between the top protective sheet and the bottom protective sheet along the circumference of the module and forms a barrier to moisture passage from outside into the protective shell from the edge area along the circumference of the module. Unlike in amorphous Si based flexible modules, the top protective sheet and the bottom protective sheet of the present module have a moisture transmission rate of less than 10⁻³ gm/m²/day, preferably less than 5×10⁻⁴ gm/m²/day. Additionally, unlike in flexible amorphous Si modules, there is a moisture sealant along the circumference of the module with similar moisture barrier characteristics.

In one embodiment, the present invention specifically provides a continuous manufacturing method to form a continuous packaging structure including a plurality of solar cell modules on elongated protective sheet bases. A moisture barrier frame is first applied on the elongated protective sheet having pre designated module areas. The moisture barrier frame is a moisture sealant (with transmission rate of <10⁻³ gm/m²/day, or moisture breakthrough time of at least 20 years through the seal) which may be applied on the elongated protective sheet as a tape, gel or liquid. The walls of the moisture barrier frame surround the borders of each of the plurality of designated module areas and form a plurality of cavities defined by the walls of the moisture barrier frame and the designated module areas. The walls of the moisture barrier frame include side walls and divider walls. The side walls may form side walls of the plurality of cavities. Divider walls separate individual cavities from one another by forming adjoining walls between two cavities. Solar cell strings are placed into each of the cavities and supported by a support material filling each cavity. The strings in the adjacent cavities are not electrically connected to one another. A pair of power output wires or terminals is extended from the strings to the outside through the side walls. To complete the assembly, a second support material is placed over the strings and a second elongated protective sheet is placed over the support material and the moisture barrier frame to enclose the plurality of cavities, thereby forming the plurality of solar cell modules. After the continuous packaging structure is completed in a continuous manner, it is laminated to form a continuous multi-module device including a plurality of laminated solar cell modules. The continuous multi-module device can be cut into sections including a desired number of laminated solar cell modules that can be used in solar energy production applications. The laminated solar cell modules in each section can also be advantageously electrically connected by connecting power output wires that outwardly extend from each solar cell module. If any solar cell module malfunctions during the application, that malfunctioning portion may be easily removed and the remaining modules are reconnected for the system to continue performing. Such removal may be only electrical in nature, i.e. the failed module is electrically taken out of the circuit by simply disconnecting its power output wires. It is also possible to physically remove the failed module by cutting it out along the two divider walls on its two sides without negatively impacting the moisture sealant nature of the divider walls.

A manufacturing process of the modules may be performed by stacking various components of the modules on a continuous elongated protective sheet provided in a roll-to roll manner. Alternatively, the manufacturing process may be performed on a continuous flexible module base, comprising a transparent elongated sheet with moisture barrier layer sections deposited onto a back surface of the transparent elongated protective sheet. The moisture barrier layer sections are physically separated from one another by a separation region, also referred to as a moisture sealant region, which fully surrounds the moisture barrier layer sections and does not contain any moisture barrier layer. In this configuration, a moisture barrier frame is applied onto the separation region and the walls of the moisture barrier frame surround each of the moisture barrier layer sections and form a plurality of cavities defined by the walls of the moisture barrier frame and the moisture barrier layer sections.

Reference will now be made to the drawings wherein like numerals refer to like parts throughout. FIG. 2A shows the cross section of an exemplary flexible module I. FIG. 2B is a top view of the same module. The exemplary flexible module 1 is an overly simplified one comprising only three cells 2a, 2b and 2c forming a string. In reality, many more cells and cell strings are used. The three cells 2a, 2b and 2c are interconnected using conductor wires 3 to form the cell string 2AA and terminal wires 4 extend to outside the perimeter formed by the top protective sheet 7 and the bottom protective sheet 8. It should be noted that in manufacturing, the wires 4 can be extended to outside the module by cutting the continuous packaging structure along line A-A as shown in FIG. 2B, and then removing material 9a that exists within the area between lines B1 and B2, thereby leaving the wires 4 extending outside the perimeter of the module. Alternately wires 4 may be joined together within the package and then only a single wire (not shown) can extend outside the module. It is also possible to take the terminal wire from the back side of the module 1 as shown in the case of terminal wire 5. It is, however, preferable to bring the terminal wires through the moisture sealant 9 in a sealed manner. If a terminal is taken out through the top protective sheet 7 or the bottom protective sheet 8, moisture may enter the module structure through the hole or holes opened for the terminals to go through. Therefore such holes would have to be sealed against moisture permeation. The cell string 2AA is covered with a top support material or encapsulant 6a and a bottom encapsulant 6b. The top encapsulant 6a and the bottom encapsulant 6b are typically the same material but they may be two different materials that melt together and surround the cell string 2AA top and bottom. The top protective sheet 7 which is transparent and resistive to moisture permeation, the bottom protective sheet 8 which is resistive to moisture permeation, and a moisture sealant 9 along the edge of the module form a protective shell 100, which is filled with the cell string 2AA, the top encapsulant 6a and the bottom encapsulant 6b. It should be noted that the thicknesses of the components shown in the figures are not to scale.

The following part of the description includes an embodiment describing how a flexible module structure such as the one shown in FIGS. 2A and 2B, as well as a modification of that flexible module structure as it relates to the terminal wires that extend outside a perimeter of the flexible module structure through the moisture sealant, may be fabricated in a continuous manner using continuous manufacturing techniques such as in-line or roll-to-roll process.

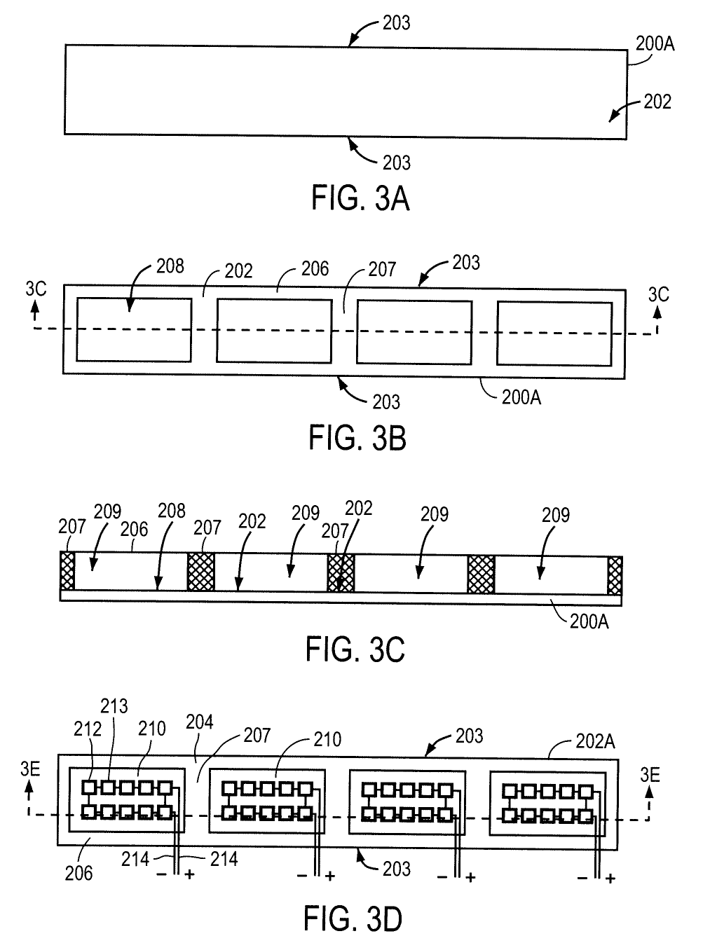

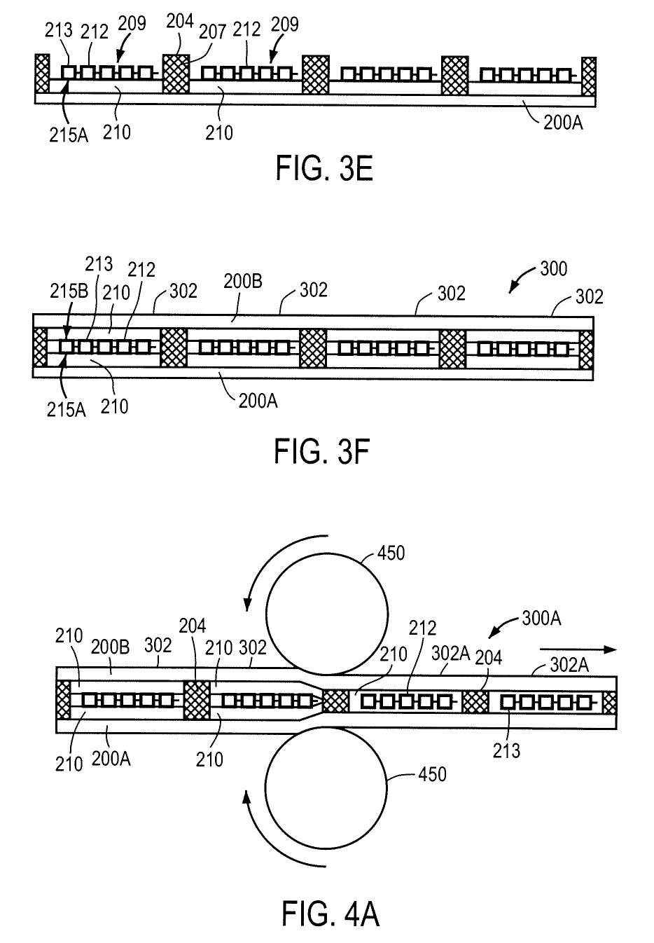

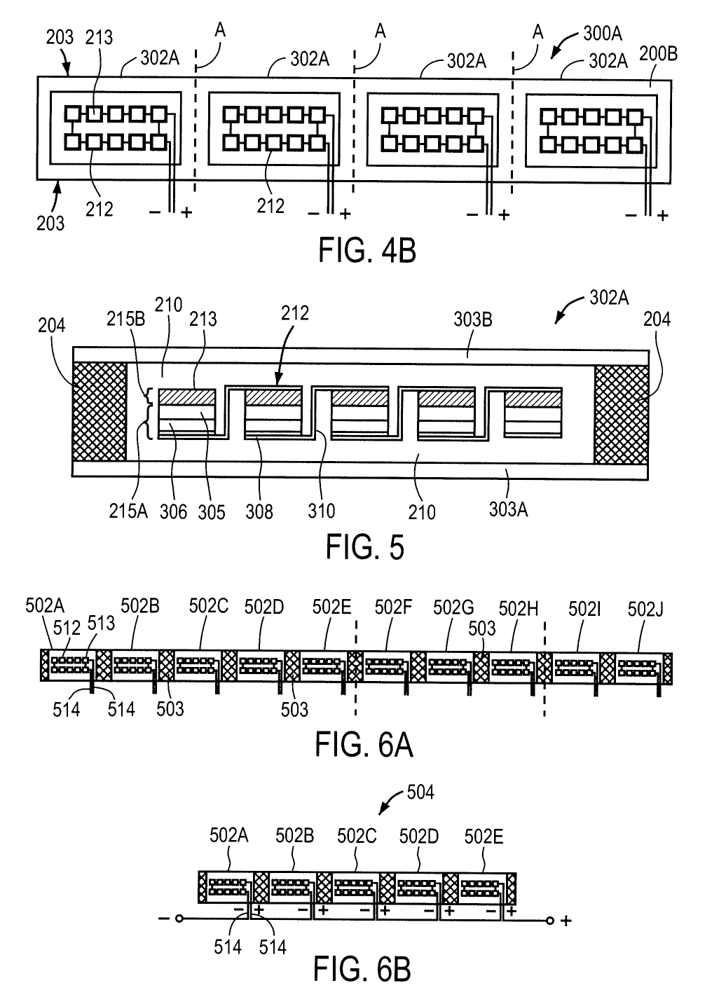

As shown in FIGS. 3A-4B, during the roll-to roll or continuous process of the invention, an initial component such as an elongated top protective sheet 200A may be first provided in a continuous or stepwise manner from a supply roll of a roll-to-roll module manufacturing system, and travels through a number of process stations, which add other components of the modules over the elongated protective sheet to manufacture a continuous packaging structure including a plurality of solar cell modules. Resulting continuous multi-module device may then be rolled onto a receiving spool to form a roll, or the continuous multi-module device may be cut into smaller sections each containing one or more modules as will be explained later.

FIG. 3A shows a first step of the process during which a section of the top elongated protective sheet 200A having a back surface 202 and two edges 203 is provided. The width of the elongated protective sheet may typically be in the range of 30-300 cm. The top elongated protective sheet forms the front side or the light receiving side of the modules that will be manufactured using the process of the invention. As shown in FIG. 3B in top view and in FIG. 3C in side view, in a second process step, a moisture sealant 204 is applied on the back surface 202 of the top elongated protective sheet 200A. The moisture sealant 204 surrounds module spaces 208 and is preferably deposited along the two edges 203 of the protective sheet 200A and between the module spaces 208. The portion of the moisture sealant 204 deposited along the edges 203A of the top elongated protective sheet 200A will be called side sealant 206 or side wall and the portion of the moisture sealant disposed between the module spaces 208 or ends of the module spaces will be called divider sealant 207 or divider wall. The moisture sealant 204 may be in the form of a tape or it may be a viscous liquid that may be dispensed onto the back surface 202 of the top elongated protective sheet 200A. The module spaces 208 are the spaces on the back surface 202 that are bordered or surrounded by the moisture sealant 204 applied on the back surface 202. As shown in FIG. 3C, the side walls 206 and the divider walls 207 of the moisture sealant 204 form a plurality of cavities 209 on the top elongated protective sheet 200A. Each cavity 209 may be defined by one module space 208 and the side walls 206 and divider walls 207 that surround that module space 208. In this respect, the moisture sealant 204 may be formed as a single piece continuous frame including the side walls and the divider walls which are shaped and dimensioned according to the desired solar cell module shape and size. When such frame is applied on the back surface 202 of the top elongated protective sheet 200A, it forms the cavities 209.

As shown in FIG. 3D in top view and in FIG. 3E in side schematic view, after disposing the moisture sealant 204, support material layers 210 or encapsulants are placed over each module space 208 within the cavities 209 and then the solar cell strings 212 are placed over the support material 210 in a face-down manner. A light receiving side 215A of each solar cell 213 in each string 212 faces toward the elongated top protective sheet 200A. Electrical leads 214 or terminals of the module may preferably be taken out of the cavity 209 through the side wall 206 of the moisture sealant 204 disposed along at least one of the long edges of the elongated protective sheet 200A, in a way that the moisture sealant 204 also seals around the electrical leads 214. As shown in the figures, solar cell strings 212 include solar cells 213 that are electrically interconnected. However, the strings 212 in each of the cavities 209 are not electrically interconnected to one another, i.e. there is no electrical connection between cells in one cavity with the cells in an adjacent cavity. It is, however, possible to have such interconnections as described in the U.S. patent application with Ser. No. 12/189,627 entitled “photovoltaic modules with improved reliability” filed Aug. 11, 2008, in which a fabricated module may comprise two or more sealed compartments (e.g. the cavities 209) each containing solar cell strings.

As shown in FIG. 3F in side schematic view, in the following step, back side 215B or base of the solar cells 213 are covered with another layer of support material 210. A back elongated protective sheet 200B is placed on the moisture sealant 204 and over the support material 210 to complete the assembly of the components of a continuous packaging structure 300 having a plurality of solar cell module structures 302.

As shown in FIG. 4A, the continuous packaging structure 300 is processed in a laminator, such as a roll laminator with rollers 450 to transform it to a continuous multi-module device 300A having a plurality of solar cell modules 302A. During the lamination process, the support material 210 in each module structure 302 melts and adheres to the solar cell strings 212 and to the top and back elongated protective sheets 200A and 200B. The moisture sealant 204 also melts and adheres to the top and back elongated protective sheets 200A and 200B.

FIG. 4B shows in top view the continuous multi-module device 300A having the solar cell modules 302A after the continuous packaging structure 300 is processed in the laminator. It should be noted that in this continuous process, support materials that do not involve chemical cross linking are preferred to support materials that involve cross linking, such as EVA. The preferred support materials include silicones and thermo plastic materials that may have melting temperatures in the range of 90-150 C. The moisture sealant 204 may also be a thermo plastic that can be melted easily in a roll laminator where pressure and heat may be applied to the module structure in presence or in absence of vacuum. It should be noted that the sealant material 204 may be dispensed in liquid form or it may be in the form of an adhesive tape that adheres on the back surface 202 of the top elongated protective sheet 200A. If liquid silicone is used as the support material 210, the silicone may be dispensed onto each module area defined by the cavity 209 formed by the back surface 202 and the sealant material 204. Therefore, the back surface 202 and the sealant material 204 acts like a container to contain the liquid silicone support material 210. The silicone support material 210 may be partially cured before the cell string is placed onto it (see FIGS. 3D and 3E) so that the cell string does not sink into the liquid and touch the back surface 202 of the top elongated protective sheet 200A. For cell strings containing flexible CIGS solar cells fabricated on stainless steel substrates, it may be difficult to keep all the cells in the string lying flat on the top surface of the semi-cured silicone layer. Therefore, a series of magnets may be used under the top elongated protective sheet 200A. These magnets pull the cell string towards the top elongated protective sheet 200A and keep them flat against the semi-cured front support material for CIGS solar cells fabricated on magnetic stainless steel foils such as Grade 430 stainless steel. With the magnets in place, the back support silicon material may be dispensed over the cell strings to cover the back side of the cells. With the magnets still in place, the silicone may be heated to be partially or fully cured. This way the cells may be trapped in between two layers of partially or fully cured silicone layers. Then the magnets may be removed, the back elongated protective sheet 200B may be placed on the moisture sealant 204 and the support material 210 to complete the formation of a continuous packaging structure 300 including a plurality of module structures. Partial curing of silicone may be achieved at a temperature range of 60-100° C.

Referring back to FIG. 4A, in order to eliminate air entrapment within the modules, the divider sealants 207 between the module structures 302 may have small cuts or holes so that as the continuous packaging structure 300 is laminated any air within a particular module structure 302, as it is transformed into a module between the rollers 450, passes into the next module structure through the uncured divider sealant between the two module structures. Since the next module is not laminated yet and thereby not sealed, entrapped air is released from this module structure and the divider sealant 207 with cuts or holes melts and heals these cuts and holes. Alternatively, to avoid air entrapment, the roll lamination may be carried out in a vacuum environment with pressure values in the order of milli-Torrs. Such vacuum levels can be obtained by building separately pumped chambers through which the continuous packaging structure 300 passes through to arrive to the chamber where the roll lamination process is carried out. For example, the continuous packaging structure may enter a first chamber through a narrow slit and then go in and out a number of chambers through narrow slits before arriving into the roll lamination chamber and then travel through several other chambers before exiting the system through a last chamber. This way the pressure may be changed from near atmospheric pressure (760 Torr) in the first and last chambers to a much lower value (such as 100 mTorr) in the lamination chamber.

FIG. 4B shows the continuous multi-module device 300A after the roll lamination process in top view wherein the light receiving side of the solar cells 213 is toward the paper plane. The continuous multi-module device 300A may be rolled into a receiving roll (not shown) with the electrical leads 214 or terminals of each module in the multi-module device protruding from the side of the receiving roll. This way the terminals do not interfere with the rolling process. The roll may be shipped for further processing or installation in the field. FIG. 4B shows the continuous multi-module device 300A obtained after the lamination and sealing process. Each of the modules 302A in this multi-module device is sealed against moisture transmission from outside environment into the module structure where the solar cell strings 212 are encapsulated.

The continuous process described above is very versatile. Once the continuous multi-module device is formed, this device may be used in a variety of ways. In one approach the continuous multi-module packaging device is cut into individual modules 302A along the dotted cut lines ‘A’ which are within the divider walls as shown in FIG. 4B, producing completely separate and sealed individual modules. The electrical leads 214 of each module 302A are on the side and does not get affected or cut by this process and the integrity of the moisture sealant 204 is not compromised anywhere along the perimeter of each module. Having electrical leads 214 come out the side along at least one of the two long edges 203 of the continuous multi-module device 302A also maximizes the active area of each module while keeping the integrity of the moisture sealant 204.

In another approach, the continuous multi-module device may be used to form monolithically integrated multi-module power supplies comprising two or more electrically interconnected modules on a common, uncut substrate or superstrate as will be described more fully below. FIG. 5 shows in side view an individual module 302A that is manufactured using the process of the present invention by cutting and separating each of the modules 302A from the continuous multi-module device 300A as shown in FIG. 4B. The solar cell string 212 is coated with the support material 210 and disposed between a top protective sheet 303A and a bottom protective sheet 303B. The top protective sheet 303A and the bottom protective sheet 303B are portions of the top and bottom elongated protective sheets 200A and 200B. The moisture sealant 204 extends between the protective sheets 303A and 300B and seals the perimeter of the module. As mentioned each solar cell 213 includes the front portion 215A or light receiving portion and the back portion 215B or base. As will be appreciated, in operation, sun light enters the module through the top protective sheet 303A and arrives at the front portion 215A of the solar cells through the support material 210. The base 215B includes a substrate and a contact layer formed on the substrate. A preferred substrate material may be a metallic material such as stainless steel, aluminum or the like. An exemplary contact layer material may be molybdenum. The front portion 215A of the solar cells may include an absorber layer 305, such as a CIGS absorber layer which is formed on the contact layer, and a transparent layer 306, such as a buffer-layer/ZnO stack, formed on the absorber layer. An exemplary buffer layer may be a (Cd,Zn)S layer. Conductive fingers 308 may be formed over the transparent layer. Conductive leads 310 electrically connect the substrate or the contact layer of one of the solar cells to the transparent layer of the next solar cell. However, the solar cells may be interconnected using any other method known in the field such as shingling.

The front protective sheet 200A may be a transparent flexible polymer film such as TEFZEL®, or another polymeric film. The front protective sheet 200A comprises a transparent moisture barrier coating which may comprise transparent inorganic materials such as alumina, alumina silicates, silicates, nitrides etc. Examples of such coatings may be found in the literature (see for example, L. Olsen et al., “Barrier coatings for CIGSS and CdTe cells”, Proc. 31^{st} IEEE PV Specialists Conf., p. 327, 2005). TEDLAR® and TEFZEL® are brand names of fluoropolymer materials from DuPont. TEDLAR® is polyvinyl fluoride (PVF) and TEFZEL is ethylene tetrafluoroethylene (ETFE) fluoropolymer. The back protective sheet 200B may be a polymeric sheet such as TEDLAR®, or another polymeric material which may or may not be transparent. The back protective sheet may comprise stacked sheets comprising various material combinations such as metallic films (like Aluminum) as moisture barrier.

As stated before, one advantage of the present invention is its versatility. Instead of cutting and separating each of the modules 302A from the continuous multi-module device 300A shown in FIG. 4B, the cutting operation may be performed to form monolithically integrated multi-module power supplies with power ratings much in excess of what is the norm today. Typical high wattage modules in the market have power ratings in the range of 200-300 W. These are structures fabricated using standard methods by interconnecting all solar cells and strings within the module structure. With the light weight and flexible structures of the present invention it is feasible to construct monolithically integrated multi-module power supplies with ratings of 600 W and over and even with power ratings of over 1000 W. A roll of a flexible and light weight power generator with multi kW rating on a single substrate can enable new applications in large scale solar power fields. It should be noted that, using the teachings of the present inventions it is possible to build a single module of multi kW rating (such as 2000-5000 W), the single module having one moisture sealant in the form of a moisture barrier frame around its perimeter (see, for example, FIG. 2A). However, manufacturing monolithically integrated multi-module power supplies comprising many individual modules each having its own moisture impermeable or moisture resistant structure has many advantages. One advantage is better reliability in such multi-module devices. If any moisture enters into any of the individual modules of the monolithically integrated flexible multi-module power supply due to a failure of the top protective sheet, the bottom protective sheet or side sealant at that module location, the moisture would not be able to travel through to other modules because of the presence of divider sealants or divider walls. Therefore, the rest of the monolithically integrated multi-module power supply would continue producing power. Such reliability improvements are discussed in detail in U.S. patent application Ser. No. 12/189,627, filed Aug. 11, 2008 titled “Photovoltaic modules with improved reliability.” Another advantage is the application flexibility offered by the method of manufacturing described above. As discussed before the continuous multi-module device 300A shown in FIG. 4B may be cut into single module structures for applications that require low wattage (100-600 W). For large rooftop applications, the continuous multi-module device may be cut to include 5-10 modules and therefore provide a monolithically integrated multi-module power supply with a rating in the range of, for example, 500-2000 W. For very large power field applications, monolithically integrated multi-module power supplies with power ratings of 1000-20000 W or higher may be employed. The important point is that all of these products can be manufactured from the same manufacturing line by just changing the steps of cutting. Presence of divider sealants between unit modules makes this possible. If divider sealants were not present, long and continuous module structures could not be cut into smaller units and be employed since moisture entering through the cut edges would limit the life of the cut modules or multi-module structures to much less than 20 years. For example, CIGS modules without a proper edge sealant would have a life of only a few years before loosing almost 50% of their power rating.

Certain advantages of the present invention may be demonstrated by an exemplary continuous multi-module device 500 shown in FIG. 6A, which may be manufactured using the process of the present invention described above. The continuous multi-module device 500, including solar cell modules 502A-502J, shown in FIG. 6A may be a portion of a longer continuous structure. Each module includes a solar cell string 512 having interconnected solar cells 513 and the light receiving side of the solar cells 213 facing toward the paper plane. Electrical leads 514 or output wires from each module are positioned along the side of the continuous multi-module device 500 as in the manner shown in FIG. 6A. The modules are separated from one another by divider walls 503 of the moisture sealant.

As shown in FIG. 6B, when an exemplary section 504 including the modules 502A-502E is separated from the continuous multi-module device 500 as described above, output wires 514 are interconnected to provide a combined power output from the modules 502A-502E of the section 504. For example if the power rating of each module is 100 W and if the cut section contains 10 modules that are interconnected, the resulting monolithically integrated multi-module power supply is a continuous, single piece 1000 W supply. If the cut section contains 20 modules a 2000 W power supply would be obtained. As shown in FIG. 6B, the interconnection between modules of the monolithically integrated multi-module power supply may be a series interconnection where the (+) terminal of each module is connected to a (−) terminal of an adjacent module. It should be noted that individual modules in the monolithically integrated multi-module power supply may also be interconnected in parallel mode.

The monolithically integrated multi-module power supply design of FIG. 6B provides advantage for deployment in the field. One advantage is the simplicity of installing a flexible, single piece, high-power power supply in the field. Elimination of handling many individual modules, elimination of many individual installation structures are some of the advantages. Another advantage is the ease of eliminating a malfunctioning module in the monolithically integrated multi-module power supply. This is possible because the inter-module interconnection terminals are outside and accessible. In section 504, for example, if the module 502 malfunctions, instead of discarding the whole section 504, the module 502B would be taken out of the circuitry by disconnecting its wires and the remaining modules 502A, 502C, 502D and 502E would be left interconnected and thus continue providing full power. Bypass diodes and other balance of system components may also be connected to the monolithically integrated multi-module power supply terminals. Although the cell strings in each module are shown to be parallel to the long edge of the monolithically integrated multi-module power supply shown in FIGS. 6A and 6B, cell strings may actually be placed in different directions in the module structure. For example, by placing cell strings perpendicular to the long edge of the monolithically integrated multi-module power supply one can reduce the length of each module (defined by the distance between the divider sealants or walls) compared to its width. This way the length of the wires used to interconnect the adjacent modules would be minimized to save cost and power loss in the interconnection wires and other hardware.

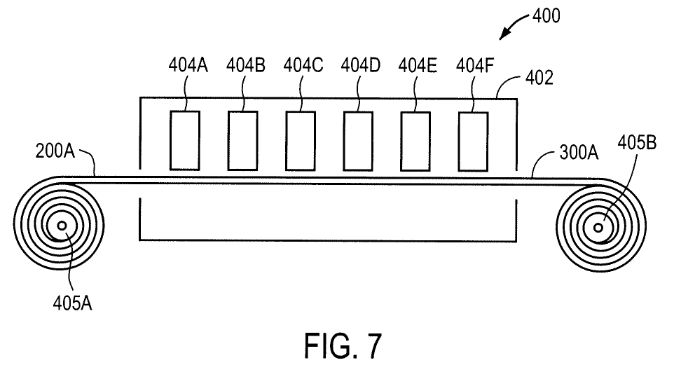

FIG. 7 shows a roll to roll system 400 to manufacture the continuous multi-module device 300A shown in FIGS. 3A-4B. The system 400 includes a process station 402 including a number of process units 404A-404F to perform above described process steps as the top protection layer 200A is supplied from the supply roll 405A and advanced through the process station 402. After processed in the lamination unit, the continuous packaging structure 300 is picked up and wrapped around the receiving roll 405B. In the following step the receiving roll 405B is taken into a cutting station to cut the continuous packaging structure 300A. In an alternative system without the receiving roll, the laminated continuous packaging structure 300 may be directly advanced into a cutting station and cut into individual modules or into monolithically integrated multi-module power supplies.

In the following, one particular configuration of a continuous multi module device with the electrical leads or terminals of each module extending from one side of the continuous multi-module device will be referred to as a first configuration. As will be described more fully below, a second particular configuration will refer to the electrical leads extending from both sides of a continuous multi-module device or a monolithically integrated multi-module power supply.

As will be more fully described below, the number and the relative distribution of the solar cells in each module may help to pre-determine whether the monolithically integrated multi-module power supply to be manufactured may have the first configuration or the second configuration. In the first configuration, positive and negative electrical leads of each module are located at the same side of the monolithically integrated multi-module power supply such that a positive electrical lead of one of the modules is preferably placed next to a negative electrical lead of an adjacent module so that they can be connected in series using a short cable to add their respective voltages. If a positive electrical lead of one of the modules is placed next to a positive electrical lead of an adjacent module, or a negative electrical lead of one of the modules is placed next to a negative electrical lead of an adjacent module, these modules may be easily interconnected in parallel to add their respective currents. In the second configuration, positive and negative electrical leads of each module are located at the opposing sides of the multi-module power supply such that a positive electrical lead of one of the modules is preferably placed next to a negative electrical lead of a following module so that they can be easily connected using a short cable. It should be noted that when leads or terminals, are referred to, these leads actually come through a junction box that may be at the edge of the module structure, in the back of the module structure near the edge, or on the front of the module structure near the edge.

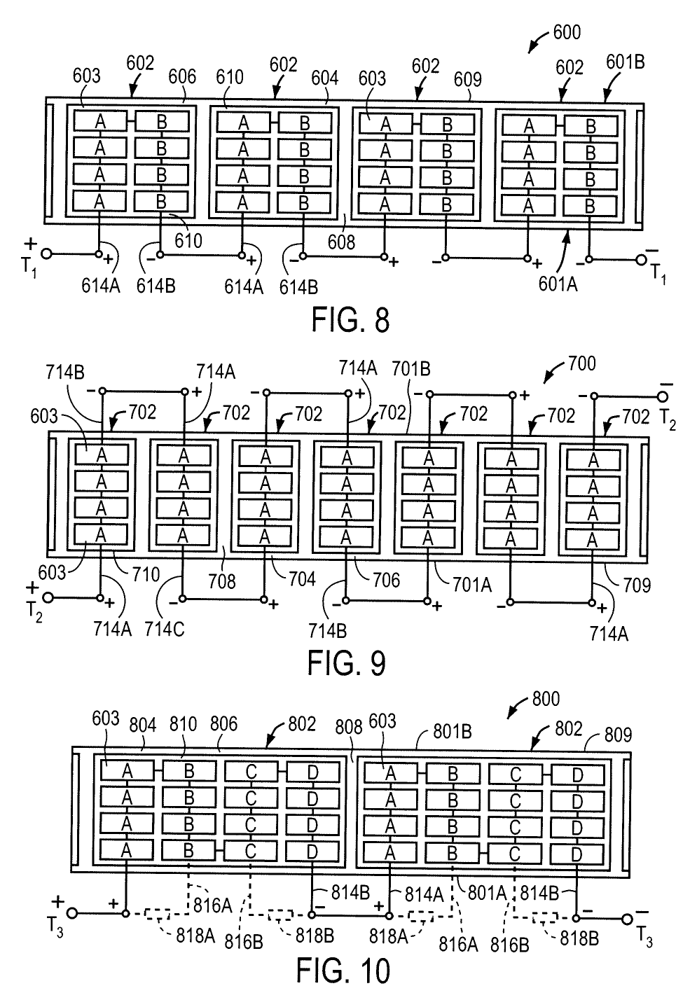

The below described invention provides a method to manufacture monolithically integrated multi-module power supplies with either the first or second configuration of electrical leads in relation with the distribution of the solar cells in each module. Accordingly the monolithically integrated multi-module power supplies shown in FIGS. 8-11 in top view include solar cells that the light receiving side of them is toward the paper plane. The solar cells in each module are organized into at least one row including at least two solar cells. In the below description, solar cells denoted with letters, A, B, C, etc., indicate a row of a module. Further, the modules with the even number of rows, e.g., rows A and B, or A, B, C and D, etc., have the first configuration of the electrical leads, i.e., the electrical leads extending from one side, and the modules with the odd number of rows, e.g., row A, or rows A, B, and C, etc., have the second configuration of the electrical leads, i.e., the electrical leads extending from both sides of the monolithically integrated multi-module power supply. The monolithically integrated multi-module power supplies shown in FIGS. 8-11 may be manufactured using the principles of the roll lamination process described above.

FIG. 8 exemplifies a monolithically integrated multi-module power supply 600 having electrical leads with the first configuration. In FIG. 8, the monolithically integrated multi-module power supply 600 with a first side 601A and a second side 601B includes a plurality of modules 602 having solar cells 603 organized in even numbered rows. In this example, each module includes two rows, wherein the solar cells in the first row are denoted with A and the solar cells in the second row are denoted with B. Each module 602 is surrounded by a moisture barrier seal frame 604 having edge seal portions 606 and divider seal portions 608, and a top elongated protective sheet (not shown) and a bottom elongated protective sheet 609. In each module 602, the solar cells 603 are surrounded by a support material 610 or encapsulant. The solar cells 603 in each module are interconnected and a first electrical lead 614A or positive lead and a second electrical lead 614 B or negative lead have the first configuration so that they extend outside the modules 602 by passing through the edge seal portions 606 on the first side 601A of the monolithically integrated multi-module power supply 600. As mentioned above, since the solar cells 603 in each module 602 are organized in two rows, i.e., rows A and B, the electrical leads 614A and 614B are located at the same side, i.e., the first side 601A. As shown in FIG. 8, when the number of rows are even numbered, due to the way the solar cells in even numbered rows are electrically connected, the first and the second electrical leads 614A and 614B in each module end up at the same side so that the polarity of the electrical leads alternates regularly along the side of the monolithically integrated multi-module power supply 600. This way, the first electrical lead 614A in one of the modules can be easily connected to the second electrical lead 614B in the following module on the same side as shown in the figure. However, if the number of rows in each module was an odd number, the positive electrical lead and the negative electrical lead will be located at the opposing sides of a monolithically integrated multi-module power supply.

FIG. 9 exemplifies a monolithically integrated multi-module power supply 700 having electrical leads with the second configuration due to the odd numbered row of solar cells. In FIG. 9, the continuous multi-module power supply 700 with a first side 701A and a second side 701B includes a module 702 having solar cells 603 organized in a single row denoted with A. Each module 702 is surrounded by a moisture barrier seal frame 704 having edge seal portions 706 and divider seal portions 708, and a top elongated protective sheet (not shown) and a bottom elongated protective sheet 709. In each module 702, the solar cells 603 are surrounded by a support material 710. The solar cells 603 in each module 702 are organized in a single row, i.e., row A, and a first electrical lead 714A or positive lead and a second electrical lead 714B or negative lead are located, in an alternating manner, at the first side 701A and the second side 701A. The solar cells 603 in each module are interconnected and the first and the second electrical lead 714A and 714B with opposing polarity are extended outside the modules 703 by passing through the edge seal portions 706 on the first side 701A and the second side 701B of the continuous multi-module power supply 700. This way, a first electrical lead 714A in one of the modules 703 can be easily connected to a second electrical lead 714B in the following module as shown in the figure. It should be noted that terminals T₁, T₂, T₃, and T₄ in the FIGS. 8-11 refer to the terminals of the monolithically integrated multi-module power supply.

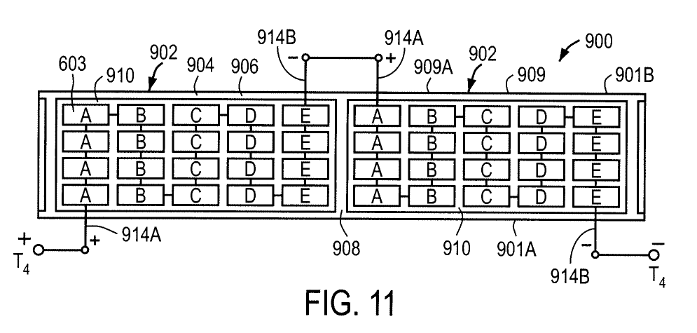

FIG. 10 exemplifies a monolithically integrated multi-module power supply 800 having electrical leads with the first configuration due to the even numbered row of solar cells. In FIG. 10, the continuous multi-module power supply 800 with a first side 801A and a second side 801B includes a module 802 having solar cells 603 organized in a single row denoted with A. Each module 802 is surrounded by a moisture barrier seal frame 804 having edge seal portions 806 and divider seal portions 808, and a top elongated protective sheet (not shown) and a bottom elongated protective sheet 809. In each module 802, the solar cells 603 are surrounded by a support material 810. The solar cells 603 in each module 802 are organized into four rows, i.e., row A, B, C and D, and a first electrical lead 814A or positive lead and a second electrical lead 814B or negative lead are located at the first side 801A. The solar cells 603 in each module are interconnected and the first and the second electrical lead 814A and 814B with opposing polarity are extended outside the modules 803 by passing through the edge seal portion 806 on the first side 801A of the monolithically integrated multi-module power supply 800. This way, a first electrical lead 814A in one of the modules 803 can be easily connected to a second electrical lead 818B in the following module. In this embodiment, there may be additional electrical leads coining from the modules to accommodate other devices such as bypass diodes. These additional electrical leads are shown schematically in FIG. 10 as 81A and 816B. The connection devices 818A and/or 818B that can be connected to the additional electrical leads may be bypass diodes and/or cables that may be used to take some rows of solar cells, which may have degraded, out of the circuit of the overall monolithically integrated multi-module power supply. If the connection devices 818A, for example, are shorting cables, use of such shorting cables may enable the modules to still operate, if the row A and B of solar cells malfunction. Since the row A and B of solar cells are shorted out by a cable ill this example, the rest of the cells in rows C and D will continue to function properly. FIG. 11 exemplifies a monolithically integrated multi-module power supply 900 having electrical leads with the second configuration due to the odd numbered row of solar cells. In FIG. 11, the monolithically integrated multi-module power supply 900 with a first side 901A and a second side 901B includes a module 902 having solar cells 603 organized in five rows denoted with A, B, C, D and E. Each module 902 is surrounded by a moisture barrier seal frame 904 having edge seal portions 906 and divider seal portions 908, and a top elongated protective sheet (not shown) and a bottom elongated protective sheet 909. In each module 902, the solar cells 603 are surrounded by a support material 910. FIGS. 8-11 show the flexibility of the designs of the present invention which may have many other configurations of solar cells.

As stated above, manufacturing monolithically integrated multi-module power supplies comprising many individual modules each having its own moisture impermeable or moisture resistant structure has many advantages. One advantage is better reliability in such multi-module devices. If any moisture enters into any of the individual modules of the monolithically integrated flexible multi-module power supply due to a failure of the top protective sheet, the bottom protective sheet or side sealant at that module location, the moisture would not be able to travel through to other modules because of the presence of divider sealants or divider walls. It should be noted that this concept of having individually sealed sections in a module structure is extendible to cases even a solar cell or a portion of a solar cell within a module may be individually sealed against moisture. Accordingly, in another embodiment, the protective shell of the module comprises top and bottom protective sheets, and an edge sealant to seal the edges at the perimeter of the protective sheets, and one or more divider sealants to divide the interior volume or space of the protective shell into sections, each section comprising at least a portion of a solar cell and an encapsulant encapsulating the front and back surfaces of the portion. The edge and divider sealants are disposed between the top and the bottom protective sheets. In this sectioned module configuration, any local defect through the protective shell will affect the solar cell s) or solar cell portions within a particular section that may be in contact with this defect and will not affect the solar cell s) or solar cell portions that are in other sections which are separated from the particular section by the divider sealants. Therefore, the solar cells or solar cell portions in the sections that are not affected by the defect will continue functioning and producing power.

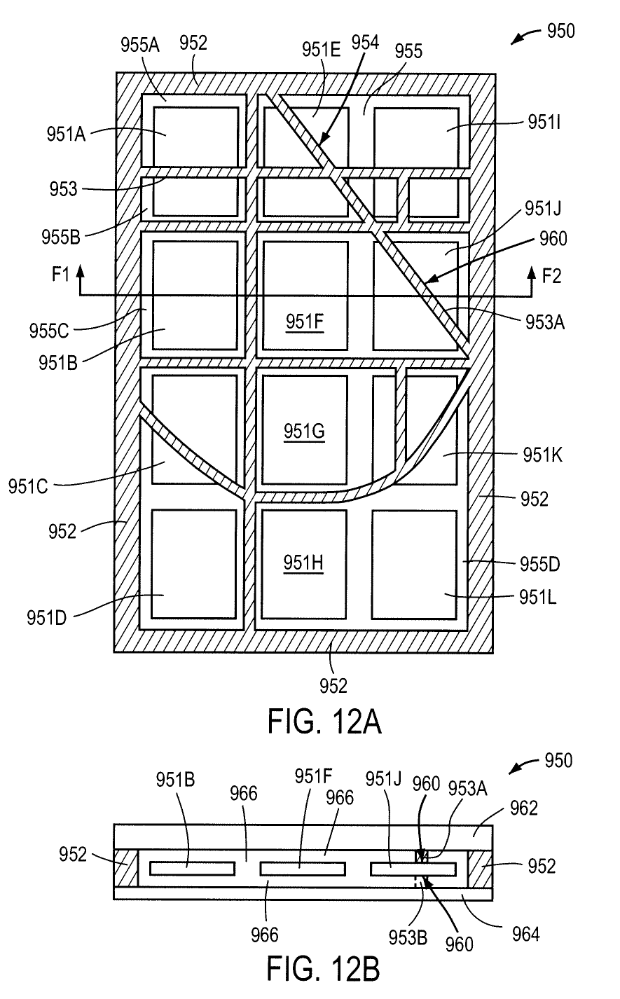

FIG. 12A shows a top or front view of a module 950. FIG. 12B shows a cross sectional view along the line F1-F2. It should be noted that the module 950 may not be the exact design of a module that one may manufacture. Rather, it is exemplary and demonstrative and is drawn for the purpose of demonstrating or showing various aspects of the present inventions in a general way in a single module structure.

The exemplary module 950 comprises twelve solar cells that are labeled as 951A, 951B, 951C, 951D, 951E, 951F, 951G, 951H, 951I, 951J, 951K, and 951L. These solar cells are electrically interconnected. The interconnections are not shown in the figure to simplify the drawing. In FIG. 3 there are gaps between the solar cells. However, as explained before, it is possible that these solar cells may be shingled and therefore, there may not be gaps between them. Cells may also be shaped differently. For example, they may be elongated with one dimension being 2-100 times larger than the other dimension. The module 950 has a top protective sheet 962 and a bottom protective sheet 964 and an edge sealant 952 between the top protective sheet 962 and the bottom protective sheet 964. The edge sealant 952 is placed at the edge of the module structure and is rectangular in shape in this example. For other module structures with different shapes, the edge sealant may also be shaped differently, following the circumference of the different shape modules. The top protective sheet 962, the bottom protective sheet 964 and the edge sealant 952 forms a protective shell.

The module 950 further comprises divider sealants 953 that are formed within the protective shell, i.e. within the volume or space created by the top protective sheet 962, the bottom protective sheet 964 and the edge sealant 952. The divider sealants 953 form a sealant pattern 954 that divides the protective shell into sealed sections 955. There are fifteen sections 955 in the exemplary module of FIG. 3. Some of the sections 955 in the middle region of the module 950 are bordered by only the divider sealants 953. Sections close to the edge of the module 950, on the other hand are bordered by divider sealants 953 as well as portions of the edge sealant 952. As can be seen from FIG. 3, each section may contain a solar cell, a portion of a solar cell, portions of more than one solar cell or more than one solar cell. For example, sections labeled as 955A and 955B each contain a different portion of the solar cell 951A, whereas the section labeled as 955C contains the single solar cell 951B. The section labeled as 955D, on the other hand, contains the solar cells 951H and 951L, as well as a portion of the solar cell 951K. The sealant pattern 954 of the divider sealants 953 may be shaped in many different ways, such as rectangular, curved, circular, etc. Portions of the divider sealants 953 may be placed in the gap between the solar cells, on the solar cells and even under the solar cells. If the divider sealants 953 or their portions are placed on the solar cells, it is preferable that they are lined up with the busbars (not shown in the figure to simplify the drawing) of the solar cells so that any possible extra shadowing of the cells by the divider sealants 953 is avoided.

As shown in FIGS. 12A and 12B, the portions of the divider sealants may be placed on divider sealant spaces 960 on the solar cells. The divider sealant spaces 960 are designated locations on the front surface or the back surface of the solar cells. The divider sealant spaces 960 do not contain any support material so that the divider sealant can be attached to the front or back side of the solar cell. It should be noted that busbars on solar cells already shadow the cell portions right under them and therefore, placing the divider sealants 953 over the busbars would not cause additional loss of area in the devices. As can be seen in the cross sectional view of the module 950 in FIG. 12B a portion 953A of the sealant pattern 954 is placed over the solar cell 951J. Another sealant portion 953B may also be present under the solar cell 951J. In other words a bottom sealant pattern (not shown) may be employed under the solar cells. The bottom sealant pattern may or may not match the shape of the sealant pattern 954. The solar cells in the module 950 are encapsulated within an encapsulant 966 that surrounds and supports them. After this general description of a general module structure employing various teachings of the present inventions more simplified module strictures will now be described to explain its unique features and benefits.

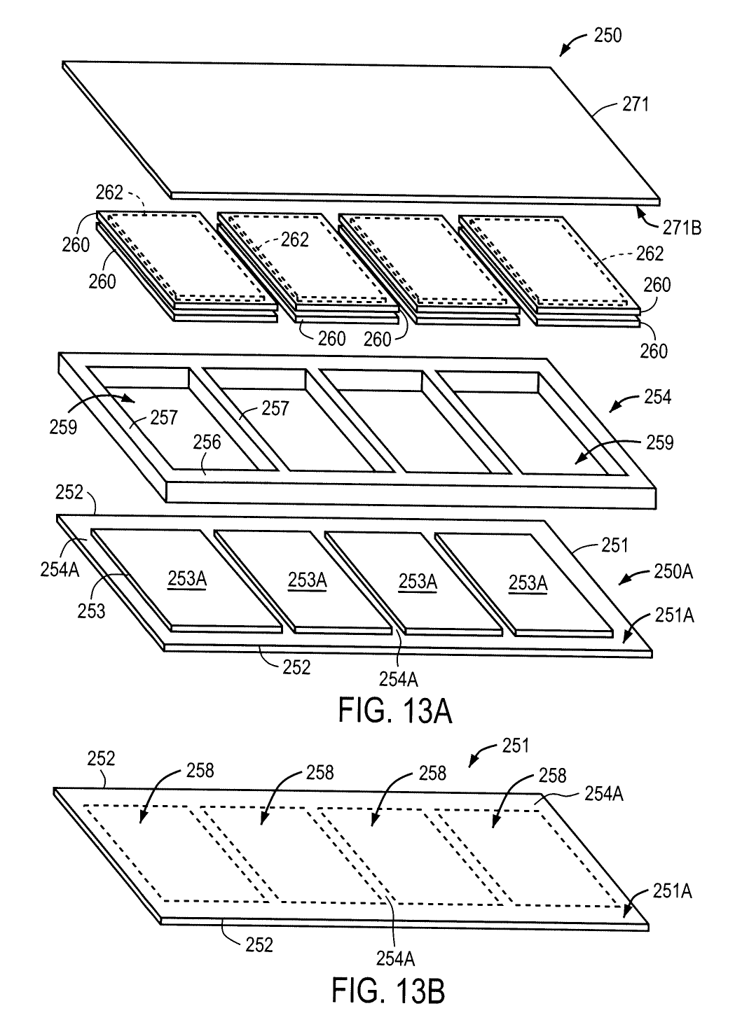

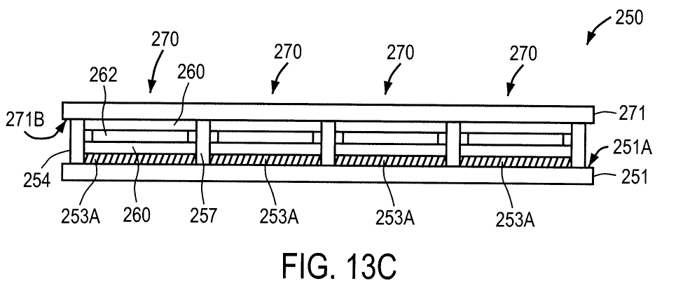

As described above in connection to FIGS. 3A-3F, during the roll-to roll or continuous or stepwise manufacturing of the power supplies or module structures an elongated top protective sheet may first be provided in a continuous or stepwise manner from a supply roll of a roll-to-roll module manufacturing system, and travels through a number of process stations, which add other components of the modules over the elongated protective sheet to form an embodiment of a continuous packaging structure or continuous multi-module device which may then be rolled onto a receiving spool to form a roll. As will be described more fully below, in another embodiment, a continuous flexible module base comprising a transparent elongated sheet and moisture barrier layer sections deposited onto the transparent elongated sheet is used to manufacture a front side for at least two solar cell modules. To form the continuous flexible module base, at least two moisture barrier layer sections are formed on a back surface of the transparent elongated sheet. A separation region that does not have the moisture barrier layer, physically separates the moisture barrier layer sections from one another and fully surrounds them. Further in the process, a moisture barrier frame surrounding each of the moisture barrier layer sections will be located on the separation region. During the roll-to roll process, the continuous flexible module base may first be provided, in a continuous or stepwise manner, from a supply roll of a roll-to-roll module manufacturing system, and travels through a number of process stations, which add other components of the modules over the elongated protective sheet to form an embodiment of a continuous packaging structure or continuous multi-module device which may then be rolled onto a receiving spool to form a roll. A process of manufacturing another embodiment of a continuous packaging structure 250 will be described using the exploded view of the continuous packaging or module structure 250 shown in FIGS. 13A and 13B. It should be noted that details of solar cell interconnection and wiring and terminals of the module structure are not shown to simplify the drawing.

Initially, a section of the top elongated protective sheet 251 having a back surface 251A and two edges 252 is provided, as shown on FIG. 13A. The top elongated protective sheet 251 forms the front side or the light receiving side of the modules that will be manufactured using the processes of the invention and therefore it is transparent.

In a second process step, a moisture barrier layer 253 is deposited on the back surface 251A of the top elongated protective sheet 251. The moisture barrier layer 253 includes moisture barrier layer portions 253A or sections, and it only covers module spaces 258. In other words, the moisture barrier layer 253 is deposited and formed only on the predetermined locations referred to as module spaces 258 on the back surface 251A of the top elongated protective sheet 251. FIG. 13B shows the module spaces 258 as dotted line rectangles which are the footprints of the interiors of future modules that will be manufactured as described herein, on the back surface 251A of the top elongated protective sheet 251. The top elongated protective sheet 251 and the moisture barrier layer 253, which comprises moisture barrier layer portions 253A, form a continuous flexible module base 250A. In one embodiment, initially, the continuous flexible module base 250A is provided at the first step of the roll-to roll process. Next, a moisture sealant 254 is applied on the back surface 251A of the top elongated protective sheet 251. The moisture sealant 254 contacts a moisture sealant region 254A, also referred to as a separation region, on the back surface 251A making a good mechanical bond with the back surface 251A at that location. FIG. 13B shows the moisture sealant region 254A or the separation region surrounding the module spaces 258. When deposited on the moisture sealant region 254A, the moisture sealant 254 surrounds the moisture barrier layer portions 253A on the module spaces 258 and is preferably deposited along the two edges 252 of the protective sheet 251 and between the moisture barrier portions 253A on the module spaces 258. The portion of the moisture sealant 254 deposited along the edges 252 of the top elongated protective sheet 251 forms a side sealant 256 or side wall and the portion of the moisture sealant disposed between the module spaces 258 or ends of the module spaces forms a divider sealant 257 or divider wall. It should be noted that placement of the moisture sealant 254 on the separation region 254A, which does not have a moisture barrier layer, assures good mechanical bond between the moisture sealant 254 and the back surface 251A at the separation region 254A. Such mechanical bond is necessary for the moisture sealant to he effective. Moisture sealants placed on moisture barrier layers often don't form good mechanical bonds and moisture can diffuse fast through such weak interfaces even though the moisture sealant itself may be a good moisture barrier,

As described above, the moisture sealant 254 may be in the form of a tape or a pre-shaped layer or it may be a viscous liquid that may be dispensed onto the moisture sealant region 254A of the back surface 251A of the top elongated protective sheet 251. When applied on the moisture sealant region 254A on the back surface 251A, the side walls 256 and the divider walls 257 of the moisture sealant 254 form a plurality of cavities 259 on the top elongated protective sheet 251. Each cavity 259 may be defined by one moisture barrier layer portion 253A and the side walls 256 and divider walls 257 that surround that moisture barrier layer portion 253A. As mentioned above, the moisture sealant 254 may be formed as a single piece continuous frame (moisture barrier frame) including the side walls and the divider walls that are shaped and dimensioned according to the desired solar module shape and size. When the moisture barrier frame is applied on the moisture sealant region 254A on the back surface 251A of the top elongated protective sheet 251, it forms the cavities 259 over the moisture barrier layer portions 253A. It should be noted that although substantially placed on the moisture sealant region 254A, some portion of the moisture sealant 254 may extend onto the moisture barrier layer portions 253A along their edges.

After disposing the moisture sealant 254, support material layers 260 or encapsulants and solar cells 262 or solar cell strings comprising two or more solar cells are placed over each moisture barrier layer portion 253A within the cavities 259. In FIG. 13A, at least one solar cell 262 or solar cell string or circuit (in dotted lines) is shown interposed between the support material layers 260. As mentioned above, the solar cells 262 or the solar cell strings or the circuits are placed over the support material layer 260 in a face-down manner. A light receiving side of each solar cell 260 or solar cell string or circuit faces toward the elongated top protective sheet 251. Electrical leads (not shown) or terminals of the module may preferably be taken out of the cavity 259 through the side wall 256 of the moisture sealant 254 disposed along at least one of the long edges of the elongated protective sheet 251, in a way that the moisture sealant 254 also seals around the electrical leads. As shown in the previous embodiments, solar cell strings or circuits include solar cells 263 that are electrically interconnected. However, the strings in each of the cavities 259 may or may not be electrically interconnected to one another.

Referring back to FIG. 13A, in the following step, a back elongated protective sheet 271 is placed on the moisture sealant 254 and over the support material 260 to complete the assembly of the components of a continuous packaging structure 250 before the lamination process. The back elongated protective sheet 271 may or may not be transparent. FIG. 13C shows a cross-section view of the completed structure of the continuous packaging structure 250 after lamination, with modules 270, the cross section being taken along the middle of the illustrated continuous packaging structure 250. It should be noted that the back elongated protective sheet 271 may have moisture barrier characteristics. There are such sheets in the market which have multi layer polymeric structures including a metallic layer, such as aluminum, as a moisture barrier. Alternatively, another set of moisture barrier layer portions 253A may be coated on a front surface 271B of the back elongated protective sheet 271 just like the barrier layer portions on the top elongated protective sheet 251.

Although aspects and advantages of the present inventions are described herein with respect to certain preferred embodiments, modifications of the preferred embodiments will he apparent to those skilled in the art.

I claim:

1. An apparatus comprising:
a continuous flexible sheet for use in fabricating flexible solar cell modules, the continuous flexible sheet including:
a front surface and a back surface, one of the front surface and the back surface including at least two moisture barrier regions and a separation region, wherein the separation region surrounds each moisture barrier region and physically separates adjacent moisture barrier regions; and
a moisture barrier layer formed on each of the moisture barrier regions but not on the separation region.

2. The apparatus of claim 1 wherein the elongated protective sheet is transparent to visible light.

3 The apparatus of claim 2 wherein the at least two moisture barrier layers are transparent to visible light.

4. The apparatus of claim 3 wherein the at least two moisture barrier layers consists of an inorganic material with a water vapor transmission rate of smaller than 10⁻³ grams/meter square/day.

5. The apparatus of claim 4 wherein the inorganic material consists of at least one of alumina, alumina silicate, a silicate, and a nitride.

6. An apparatus comprising:
a monolithically integrated multi-module power supply, the monolithically integrated multi-module power supply including:
a top transparent elongated protective sheet having a top sheet inner surface and a top sheet outer surface;
a bottom elongated protective sheet having a bottom sheet inner surface and a bottom sheet outer surface;
a moisture sealant disposed between the bottom sheet inner surface and the top sheet inner surface to form at least two sealed chambers, wherein each sealed chamber includes a ceiling formed by a portion of the top sheet inner surface and a floor formed by a portion of the bottom sheet inner surface, and wherein the moisture sealant is in physical contact with the top sheet inner surface and the bottom sheet inner surface;
a moisture barrier layers covering each of the ceilings of each of the sealed chambers;
at least two solar cells that are electrically interconnected and disposed in each of the at least two sealed chambers, each solar cell having a front light receiving side and a back side wherein the front light receiving side faces the top transparent elongated protective sheet; and
a support material that at least partially encapsulates each solar cell on both the front light receiving side and the back side.

7. The apparatus of claim 6, further including moisture barrier layers covering the floors of the at least two sealed chambers.

8. The apparatus of claim 7, wherein the bottom elongated protective sheet is transparent.

9. The apparatus of claim 6, wherein the bottom elongated protective sheet comprises a moisture barrier film.

10. A method of manufacturing a photovoltaic module comprising the steps of:
providing a transparent elongated protective sheet having a front surface and a back surface, the back surface including two or more moisture barrier regions and a separation region, wherein the separation region surrounds each moisture barrier region and physically separates adjacent moisture barrier regions;
forming a moisture barrier layer on each moisture barrier region but not on the separation region;
disposing a solar cell circuit over each of the moisture barrier layers, each solar cell circuit including a front light receiving side and a back substrate side;
disposing a moisture sealant onto the separation region thereby forming two or more cavities, each cavity being at a location corresponding to the two or more moisture barrier regions, each cavity holding one solar cell circuit with the front light receiving side facing the transparent elongated protective sheet;
at least partially covering each solar cell circuit with a support material on both the front light receiving side and the back substrate side;
placing a second protective sheet over the support material and the moisture sealant to enclose the at least two cavities and to form a stack; and
heating the stack to form the photovoltaic module.

11. The method of claim 10 wherein the transparent elongated protective sheet is transparent to visible light.

12. The method of claim 11 wherein the two or more moisture barrier layers are transparent to visible light.

13. The method of claim 12 wherein the two or more moisture barrier layers consist of an inorganic material with a water vapor transmission rate of smaller than 10⁻³ grams/meter square/day.

14. The method of claim 13 wherein the inorganic material consists of at least one of alumina, alumina silicate, a silicate, and a nitride.
